(19) United States
(12) Patent Application Publication
(10) Pub. No.: US 2006/0083148 A1
(43) Pub. Date: Apr. 20, 2006

(54) Planar light emitting device

(75) Inventor: Mitsuru Yokoyama, Osaka (JP)

Correspondence Address: BRINKS HOFER GILSON & LIONE, P.O. BOX 10395, CHICAGO, IL, 60610, US

(73) Assignee: KONICA MINOLTA HOLDINGS, INC.

(21) Appl. No.: 11/244,709

(22) Filed: Oct. 6, 2005

(30) Foreign Application Priority Data
Oct. 18, 2004 (JP) 2004-302947
Oct. 29, 2004 (JP) 2004-317214

(51) Int. Cl. G11B 7/00

(52) U.S. Cl. 369/112.04; 369/100

(57) ABSTRACT

A planar light emitting device 1 has a light emitting layer 5 that is formed on a glass substrate 2 and that emits light when a voltage is applied thereto or a current is injected thereinto and a two-dimensional diffraction grating 30 that has a first and a second medium 31 and 32 having different refractive indices and that has the second medium 32 arrayed two-dimensionally in the first medium 31. In the two-dimensional diffraction grating 30, the ratio of the area occupied by the second medium 32 to the sum of the area occupied by the first medium 31 and the area occupied by the second medium 32 is 25% or more but 60% or less.

This application is based on Japanese Patent Application No. 2004-302947 filed on Oct. 18, 2004 and Japanese Patent Application No. 2004-317214 filed on Oct. 29, 2004, the contents of which are hereby incorporated by reference.

### BACKGROUND OF THE INVENTION

1. Field of the Invention

The present invention relates to a planar light emitting device, such as an organic EL device or inorganic EL device, having a light emitting layer.

2. Description of Related Art

There have conventionally been proposed various types of planar light emitting device. For example, in a planar light emitting devices that exploit electroluminescence, such as an organic or inorganic EL device, on a glass substrate, a transparent electrode of ITO or the like is formed, and, on top thereof, a light emitting layer is formed that emits light when a voltage is applied thereto. Further on top of the light emitting layer, a back electrode of aluminum or the like is formed.

The light emitting layer is formed of an organic compound or the like, and emits light as a result of recombination between holes injected from the transparent electrode and electrons injected from the back electrode. The light produced in the light emitting layer passes through the transparent electrode and the glass substrate, and exits via the exit surface of the glass substrate. Part of the light is reflected on the back electrode to reach the transparent electrode, and then exits via the exit surface.

In this planar light emitting device, the interface between the light emitting layer and the transparent electrode, the interface between the transparent electrode and the glass substrate, and the exit surface guide light by totally reflecting the light incident thereon at angles of incidence equal to or smaller than the critical angle. As a result, disadvantageously, the amount of light exiting via the exit surface is small, resulting in low light extraction efficiency. In particular, in organic EL devices, higher light extraction efficiency is sought to obtain longer lifetimes and other benefits. Higher light extraction efficiency is sought, in fact, commonly in any other type of planar light emitting device (for example, LEDs also are a type of planar light emission device).

To overcome the above-mentioned disadvantages, Japanese Patent Application Laid-open No. H11-283751 discloses a planar light emitting device having a two-dimensional diffraction grating. This planar light emitting device has a two-dimensional diffraction grating at the boundary between a transparent electrode and a glass substrate. The light produced in a light emitting layer is diffracted by the two-dimensional diffraction grating, with the result that the angles of incidence at which light reaches the exit surface of the glass substrate become larger than the critical angle. This reduces the light totally reflected at the interface between the transparent electrode and the glass substrate and at the exit surface, leading to higher light extraction efficiency.

In recent years, planar light emitting devices such as organic EL devices have been finding increasingly wide application, and nowadays, in planar light emitting devices, light extraction efficiency even higher than achieved with the planar light emitting device disclosed in Japanese Patent Application Laid-open No. H11-283751 mentioned above is sought.

### SUMMARY OF THE INVENTION

An object of the present invention is to provide a planar light emitting device that offers higher light extraction efficiency.

To achieve the above object, according to one aspect of the present invention, a planar light emitting device is provided with: a light emitting layer that is formed on a substrate and that emits light when a voltage is applied thereto or a current is injected thereinto; and a two-dimensional diffraction grating that has a first and a second medium having different refractive indices and that has the second medium arrayed two-dimensionally in the first medium. Here, in the two-dimensional diffraction grating, the ratio of the area occupied by the second medium to the sum of the area occupied by the first medium and the area occupied by the second medium is 25% or more but 60% or less.

In this structure, the two-dimensional diffraction grating is formed by arraying circular, rectangular, triangular, or otherwise shaped portions of the second medium two-dimensionally and periodically in the first medium. Thus, the first medium is dotted with the second medium so that the ratio of the area of the second medium to the sum of the areas of the first and second media is 25% or more but 60% or less. Accordingly, in a case where the two-dimensional diffraction grating is composed solely of the first and second media, the second medium occupies 25% or more but 60% or less of the total area of the two-dimensional diffraction grating. In a case where the diameter of each portion of the second medium varies in the depth direction, then, with respect to the mean value of the diameter or the diameter as measured on a cross-section where it takes its median value, the above relationship holds between the areas of the first and second media.

According to another aspect of the present invention, a planar light emitting device is provided with: a light emitting layer that is formed on a substrate and that emits light when a voltage is applied thereto or a current is injected thereinto; and a diffractive layer formed with a two-dimensional diffraction grating that has a first and a second medium having different refractive indices and that has the second medium arrayed two-dimensionally in the first medium. Here, in the diffractive layer, the ratio of the area occupied by the second medium to the sum of the area occupied by the first medium and the area occupied by the second medium is 25% or more but 60% or less.

In this structure, the first medium is dotted with cylindrical, prismatic, conic, pyramidal, conic-trapezoid, pyramidal-trapezoid, or otherwise shaped portions of the second medium so that the ratio of the volume of the second medium to the sum of the volumes of the first and second media is 25% or more but 60% or less. Accordingly, in a case where the two-dimensional diffraction grating is composed solely of the first and second media, the second medium occupies 25% or more but 60% or less of the total volume of the diffractive layer.

According to another aspect of the present invention, a planar light emitting device is provided with: a light emitting layer that is formed on a substrate and that emits light when a voltage is applied thereto or a current is injected thereinto; and a dispersive member that has a first and a second medium having different refractive indices and that has the second medium arrayed two-dimensionally in the first medium. Here, in the dispersive member, the ratio of the area occupied by the second medium to the sum of the area occupied by the first medium and the area occupied by the second medium is 25% or more but 60% or less.

In this structure, the dispersive member is formed by arraying the second medium non-periodically in the first medium. Thus, the first medium is dotted with the second medium so that the ratio of the area of the second medium to the sum of the areas of the first and second media is 25% or more but 60% or less. Accordingly, in a case where the dispersive member is composed solely of the first and second media, the second medium occupies 25% or more but 60% or less of the total area of the dispersive member. In a case where the diameter of each portion of the second medium varies in the depth direction, then, with respect to the mean value of the diameter or the diameter as measured on a cross-section where it takes its median value, the above relationship holds between the areas of the first and second media.

According to another aspect of the present invention, a planar light emitting device is provided with: a light emitting layer that is formed on a substrate and that emits light when a voltage is applied thereto or a current is injected thereinto; and a dispersive layer formed with a dispersive member that has a first and a second medium having different refractive indices and that has the second medium arrayed two-dimensionally in the first medium. Here, in the dispersive layer, the ratio of the area occupied by the second medium to the sum of the area occupied by the first medium and the area occupied by the second medium is 25% or more but 60% or less.

In this structure, the first medium is dotted with cylindrical, prismatic, conic, pyramidal, conic-trapezoid, pyramidal-trapezoid, or otherwise shaped portions of the second medium so that the ratio of the volume of the second medium to the sum of the volumes of the first and second media is 25% or more but 60% or less. Accordingly, in a case where the dispersive layer is composed solely of the first and second media, the second medium occupies 25% or more but 60% or less of the total volume of the dispersive layer.

According to another aspect of the present invention, a planar light emitting device is provided with: a light emitting layer that is formed on a substrate and that emits light when a voltage is applied thereto or a current is injected thereinto; and a two-dimensional diffraction grating that has a first and a second medium having different refractive indices arrayed two-dimensionally. Here, the two-dimensional diffraction grating is non-rotation-symmetric.

In this structure, the two-dimensional diffraction grating is formed by arraying the first and second media two-dimensionally and periodically. The two-dimensional diffraction grating is non-rotation-symmetric. The light produced in the light emitting layer is diffracted by the two-dimensional diffraction grating so as to exit from the planar light emitting device.

According to another aspect of the present invention, a planar light emitting device is provided with: a light emitting layer that is formed on a substrate and that emits light when a voltage is applied thereto or a current is injected thereinto; and a two-dimensional diffraction grating that has a first and a second medium having different refractive indices arrayed two-dimensionally. Here, the two-dimensional diffraction grating has a periodic structure which is classified into pl, pm, pg, or cm by a classification method under IUC (1952).

In this structure, the two-dimensional diffraction grating is formed by arraying the first and second media two-dimensionally and periodically. The two-dimensional diffraction grating is composed of a wallpaper group represented by one of IUC symbols pl, pm, pg, and cm, and is non-rotation-symmetric. The light produced in the light emitting layer is diffracted by the two-dimensional diffraction grating so as to exit from the planar light emitting device.

### BRIEF DESCRIPTION OF THE DRAWINGS

FIG. 1 a front view of the planar light emitting device of a first embodiment of the invention;

FIG. 2 is a plan view of the two-dimensional diffraction grating used in the planar light emitting device of the first embodiment of the invention;

FIG. 3 is a front view of the two-dimensional diffraction grating used in the planar light emitting device of the first embodiment of the invention;

FIG. 4 is a diagram showing how light is propagated in the planar light emitting device of the first embodiment of the invention;

FIG. 5 is a diagram showing how light is propagated in a conventional planar light emitting device;

FIGS. 6A to 6D are plan views of other examples of the two-dimensional diffraction grating used in the planar light emitting device of the first embodiment of the invention;

FIG. 7 is a plan view of another example of the two-dimensional diffraction grating used in the planar light emitting device of the first embodiment of the invention;

FIG. 8 is a front view of the planar light emitting device of a second embodiment of the invention;

FIG. 9 is a plan view of the dispersive member used in the planar light emitting device of the second embodiment of the invention;

FIG. 10 is a diagram showing the light extraction efficiency of the planar light emitting device of the first embodiment of the invention;

FIG. 11 is a diagram showing the light extraction efficiency of the planar light emitting device of the second embodiment of the invention;

FIG. 12 is a diagram showing the light extraction efficiency of the planar light emitting device of a third embodiment of the invention;

FIG. 13 is a diagram showing the light extraction efficiency of the planar light emitting device of a fourth embodiment of the invention;

FIG. 14 is a diagram showing an example in which only the electric field components of light distributed over the two-dimensional refractive index period distribution of the two-dimensional diffraction grating used in the planar light emitting device shown in FIG. 2 are extracted;

FIG. 15 is a diagram showing an example in which only the electric field components of light distributed over the two-dimensional refractive index period distribution of the two-dimensional diffraction grating used in the planar light emitting device shown in FIG. 6D are extracted;

FIG. 16 is a diagram showing the electric field distribution of the two-dimensional diffraction grating used in the planar light emitting device shown in FIG. 2;

FIG. 17 is a diagram showing the electric field distribution of the two-dimensional diffraction grating used in the planar light emitting device shown in FIG. 6D;

FIG. 18 is a plan view of the two-dimensional diffraction grating used in the planar light emitting device of the third embodiment of the invention;

FIG. 19 is a diagram showing an example in which only the electric field components of light distributed over the two-dimensional refractive index period distribution of the two-dimensional diffraction grating used in the planar light emitting device of the third embodiment of the invention are extracted;

FIG. 20 is a diagram showing an example in which only the electric field components of light distributed over the two-dimensional refractive index period distribution of the two-dimensional diffraction grating used in the planar light emitting device of the third embodiment of the invention are extracted;

FIG. 21 is a diagram illustrating how electric fields cancel one another in the two-dimensional dimensional diffraction grating used in the planar light emitting device of the third embodiment of the invention;

FIG. 22 is a diagram showing the electric field distribution of the two-dimensional diffraction grating used in the planar light emitting device of the third embodiment of the invention;

FIG. 23 is a diagram showing the electric field distribution of the two-dimensional diffraction grating used in the planar light emitting device of the third embodiment of the invention;

FIG. 24 is a perspective view of another structure of the two-dimensional diffraction grating used in the planar light emitting device of the third embodiment of the invention;

FIG. 25 is a plan view of the two-dimensional diffraction grating used in the planar light emitting device of the fourth embodiment of the invention;

FIG. 26 is a plan view of the two-dimensional diffraction grating used in the planar light emitting device of a fifth embodiment of the invention;

FIG. 27 is a plan view of the two-dimensional diffraction grating used in the planar light emitting device of a sixth embodiment of the invention;

FIG. 28 is a plan view of the two-dimensional diffraction grating used in the planar light emitting device of a seventh embodiment of the invention;

FIG. 29 is a plan view of the two-dimensional diffraction grating used in the planar light emitting device of an eighth embodiment of the invention;

FIG. 30 is a plan view of the two-dimensional diffraction grating used in the planar light emitting device of a ninth embodiment of the invention;

FIG. 31 is a plan view of the two-dimensional diffraction grating used in the planar light emitting device of a tenth embodiment of the invention; and

FIG. 32 is a plan view of the two-dimensional diffraction grating used in the planar light emitting device of an eleventh embodiment of the invention.

### DETAILED DESCRIPTION OF PREFERRED EMBODIMENTS

Hereinafter, embodiments of the present invention will be described with reference to the accompanying drawings. FIG. I is a side view of the planar light emitting device of a first embodiment of the invention. In the planar light emitting device 1, on a glass substrate 2 as a transparent substrate, there are laid a diffractive layer 3, a transparent electrode 4, a light emitting layer 5, and a back electrode 6 in this order. Although a glass substrate is used here, a transparent substrate formed of any other material, such as transparent resin, may be used instead. The transparent electrode 4 is formed of a transparent, electrically conductive material such as ITO or IZO.

The light emitting layer 5 is formed of a light emitting material that is an organic substance. Thus, the planar light emitting device 1 is built as an organic EL device. The following description assumes that the planar light emitting device 1 is an organic EL device, but applies equally to any other type of light emitting device of the planar light emission type; for example, the planar light emitting device 1 may be an inorganic EL device or an LED.

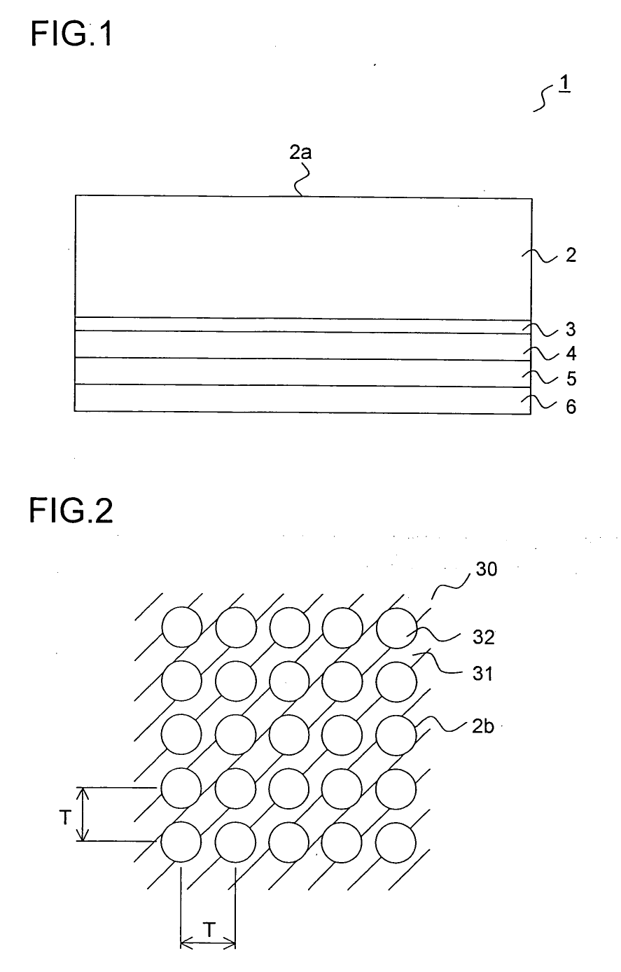

The light emitting layer 5 may be composed of a plurality of functionally diversified organic substance layers laid on one another. Between the light emitting layer 5 and each of the electrodes, there may additionally be provided another functional layer, such as an electric charge injection layer, electric charge transfer layer, or buffer layer. Although the organic EL device shown in FIG. 1 is of a so-called bottom emission type, it may be of a top emission type.

The back electrode 6 is formed of a material, such as aluminum, that reflects light. When a voltage is applied between the transparent electrode 4 and the back electrode 6, holes injected from the transparent electrode 4 and electrons injected from the back electrode 6 recombine together, thereby causing the light emitting layer 5 to emit light.

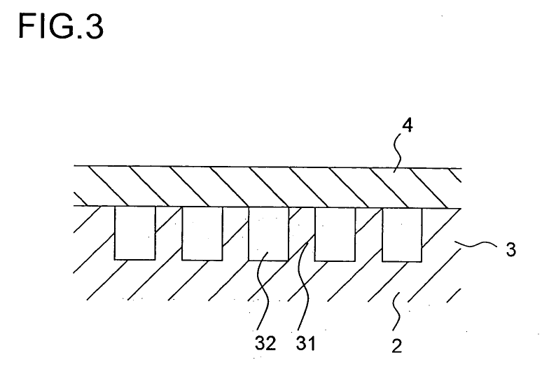

The diffractive layer 3 is formed with a two-dimensional diffraction grating that has different media having different refractive indices arrayed two-dimensionally and periodically. FIGS. 2 and 3 are a plan view and a side sectional view, respectively, of the two-dimensional diffraction grating 30 forming the diffractive layer 3. The two-dimensional diffraction grating 30 is formed by forming cylindrical holes 2b in the glass substrate 2 with a predetermined period. This is achieved, for example, by patterning using photolithography combined with dry etching. In this way, in a first medium 31, namely the glass substrate 2 having a refractive index of 1.5, a second medium 32, namely hollow holes having a refractive index of 1, is arrayed to form a tetragonal lattice.

The two-dimensional periodic structure is formed with a pitch of 0.1 μm to 4 μm. Moreover, the ratio of the area occupied by the second medium 32 to the sum of the areas occupied by the first and second media 31 and 32 is 25% or more but 60% or less. That is, in a case where the two-dimensional diffraction grating 30 is composed solely of the first and second media 31 and 32, the second medium 32 occupies 25% or more but 60% or less of the total area.

In the planar light emitting device I structured as described above, when a voltage is applied or a current is injected between the transparent electrode 4 and the back electrode 6, the light emitting layer 5 emits light. The emitted light passes through the transparent electrode 4, and is then diffracted by the diffractive layer 3 in the direction of the exit surface 2a (see FIG. 1). The light then passes through the glass substrate 2, and exits via the exit surface 2a. Part of the light is reflected on the back electrode 6 to reach the transparent electrode 4, and is then diffracted likewise by the diffractive layer 3 to exit via the exit surface 2a.

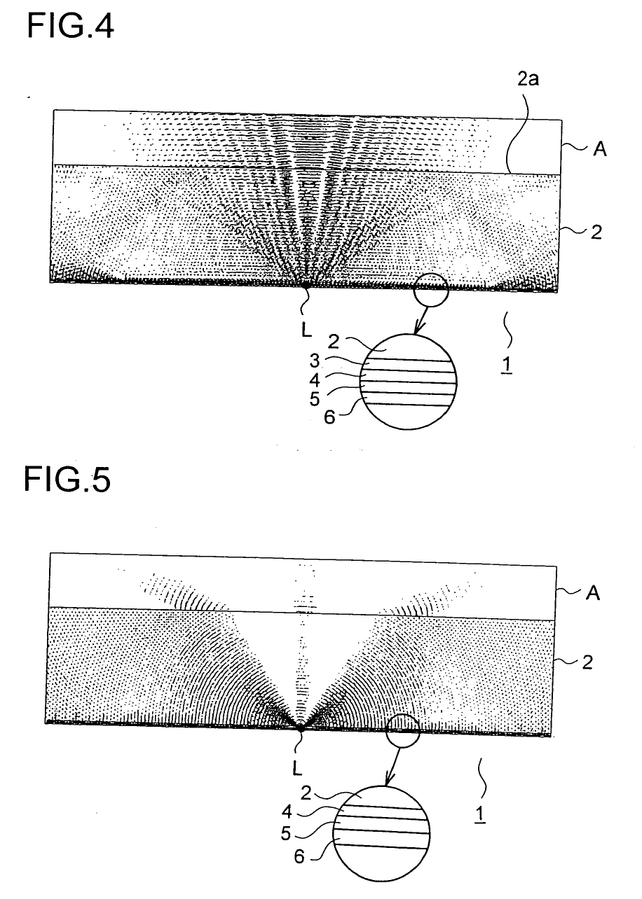

FIG. 4 shows how light is propagated in the planar light emitting device 1 of this embodiment, simulating a typical case where light is produced at a single point source L in the light emitting layer 5. An air layer is indicated as “A”. For comparison, FIG. 5 shows a case where the diffractive layer 3 is omitted. For easier understanding, an enlarged view of the device is shown together. As will be understood from these diagrams, the planar light emitting device 1 of this embodiment emits a larger amount of light via the exit surface 2a thereof, and thus offers higher light extraction efficiency.

In this embodiment, in the two-dimensional diffraction grating 30 having the second medium 32 arrayed in the first medium 31, the ratio of the area occupied by the second medium 32 to the sum of the areas occupied by the first and second media 31 and 32 is 25% or more but 60% or less. This permits the light exiting from the glass substrate 2 to be extracted with higher efficiency than ever. Moreover, the two-dimensional diffraction grating 30 is formed with a pitch T of 0.1 μm to 4 μm. This makes it easy to design the two-dimensional diffraction grating 30 to diffract light in a desired direction.

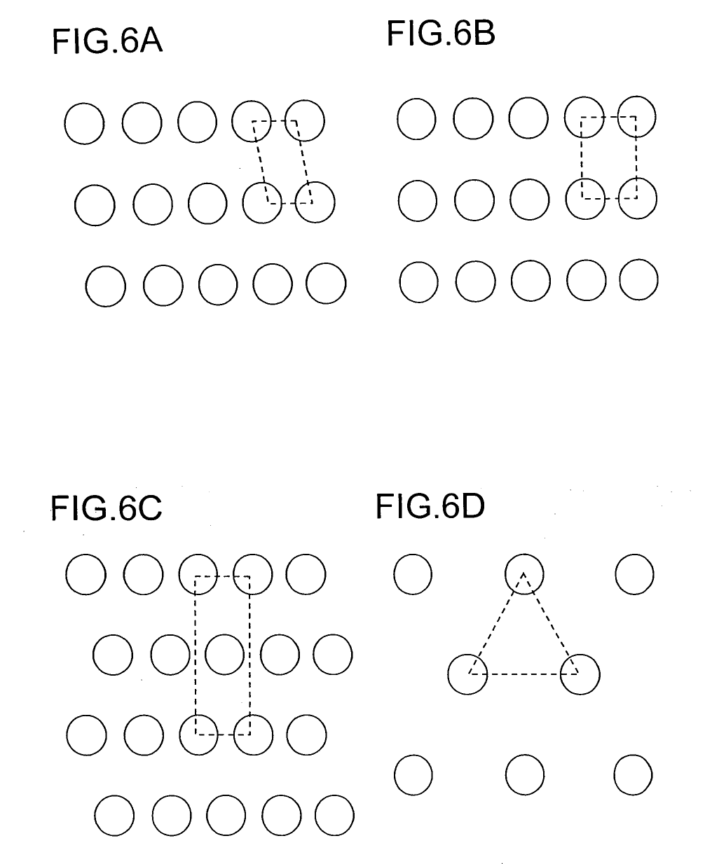

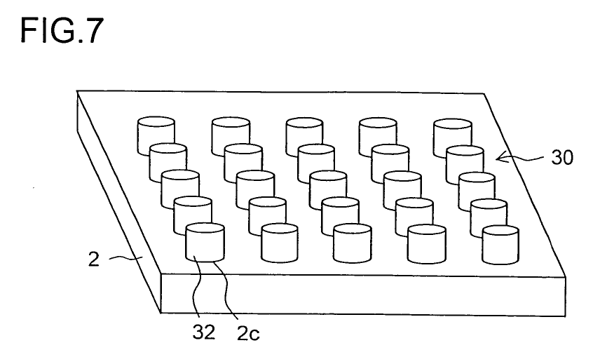

The diffractive layer 3, when formed between the transparent electrode 4 and the glass substrate 2, is comparatively easy to produce and, since there it is located close to the light emitting layer 5, tends to work effectively. Alternatively, the diffractive layer 3 may be formed on the exit surface 2a. The two-dimensional diffraction grating 30 may be formed to have, instead of a tetragonal lattice specifically described above, an oblique lattice (see FIG. 6A), rectangular lattice (see FIG. 6B), face-centered lattice (see FIG. 6C), or hexagonal lattice (see FIG. 6D).

The second medium 32 has simply to have a different refractive index from the first medium 31. Thus, the holes 2b (see FIG. 2) may be filled with a transparent, electrically conductive material such as ITO. In this case, the two-dimensional diffraction grating 30 has, as the first medium 31, glass having a refractive index of 1.5 and, as the second medium 32, for example, ITO having a refractive index of 1.9.

The holes 2b filled with the second medium 32 may be formed in, instead of a cylindrical shape as specifically described above, a conic, pyramidal, conic-trapezoid, pyramidal-trapezoid, or other shape so that their cross-sectional area varies in the depth direction. In this case, the ratio of the volume occupied by the second medium 32 to the sum of the volumes occupied by the first and second media 31 and 32 is 25% or more but 60% or less.

Alternatively, as shown in FIG. 7, the two-dimensional diffraction grating 30 may be formed by removing part of the glass substrate 2 so as to leave columnar portions 2c and then filling a material, such as air or ITO, having a different refractive index from the glass substrate 2, around the columnar portions 2c. In this case, the medium that fills around the columnar portions 2c is the first medium 31, and the columnar portions 2c is the second medium 32.

The diffractive layer 3 may be formed between the transparent electrode 4 and the light emitting layer 5. This too helps obtain higher light extraction efficiency. In this case, the first medium 31 is a transparent, electrically conductive material, and the second medium 32 is the material of which the light emitting layer 5 is formed, that is, air, an organic substance, or the like. Alternatively, in a similar manner as shown in FIG. 7 described above, columnar portions 2c of the second medium 32 may be formed of a transparent, electrically conductive material.

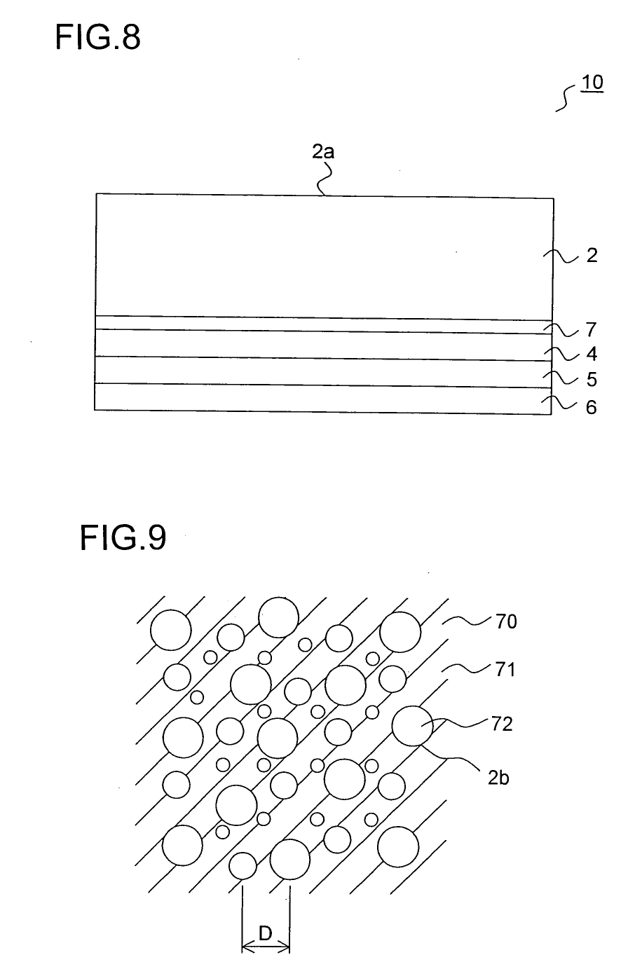

FIG. 8 is a side view of a planar light emitting device 10 of a second embodiment of the invention. In the planar light emitting device 10 of this embodiment, instead of the diffractive layer 3 provided in the embodiment shown in FIGS. 1 to 7, a dispersive layer 7 is provided. In other respects, the structure here is the same as in the first embodiment.

The dispersive layer 7 is formed with a dispersive member that has different media having different refractive indices arrayed non-periodically. FIG. 9 is a plan view of an example of the dispersive member 70 forming the dispersive layer 7. The dispersive member 70 is formed by forming cylindrical holes 2b randomly in a glass substrate 2. The holes 2b are formed, for example, by forming a mask layer by photolithography or the like involving ultraviolet irradiation through a mask having a random pattern formed therein and then performing dry etching. In this way, in the first medium 31, namely the glass substrate 2 having a refractive index of 1.5, the second medium 32, namely hollow holes having a refractive index of 1, is arrayed to form the dispersive member 70, which disperses light.

The second medium 32 is so arrayed that the mean interval D between two adjacent portions thereof (the mean distance from the center of one portion of the second medium 32 to another) is 0.1 μm to 4 μm. Moreover, the ratio of the area occupied by the second medium 32 to the sum of the areas occupied by the first and second media 31 and 32 is 25% or more but 60% or less. That is, in a case where the dispersive member 70 is composed solely of the first and second media 31 and 32, the second medium 32 occupies 25% or more but 60% or less of the total area of the dispersive member 70.

In the planar light emitting device 1 structured as described above, when a voltage is applied between the transparent electrode 4 and the back electrode 6, the light emitting layer 5 emits light. The emitted light passes through the transparent electrode 4, and is then dispersed by the dispersive layer 7 in the direction of the exit surface 2a (see FIG. 1). The light then passes through the glass substrate 2, and exits via the exit surface 2a.

In this embodiment, in the dispersive member 70 having the second medium 32 arrayed in the first medium 31, the ratio of the area occupied by the first medium 31 to the sum of the areas occupied by the first and second media 31 and 32 is 25% or more but 60% or less. Thus, as in the first embodiment, the light exiting from the glass substrate 2 can be extracted with higher efficiency than ever. Moreover, the mean value of the intervals D between two adjacent portions of the second medium 32 is 0.1 μm to 4 μm. This makes it easy to design the dispersive member 70 to disperse light in a desired direction.

Although the dispersive layer 7 is formed between the transparent electrode 4 and the glass substrate 2, it may alternatively be formed at the interface between the transparent electrode and the light emitting layer 5, or on the exit surface 2a. The second medium 32 has simply to have a different refractive index from the first medium 31. Thus, the holes 2b (see FIG. 9) may be filled with a transparent, electrically conductive material such as ITO.

The holes 2b filled with the second medium 32 may be formed in, instead of a cylindrical shape as specifically described above, a prismatic shape, or even a conic, pyramidal, conic-trapezoid, or a pyramidal-trapezoid shape so that their cross-sectional area varies in the depth direction. In this case, the ratio of the volume occupied by the second medium 32 to the sum of the volumes occupied by the first and second media 31 and 32 is 25% or more but 60% or less. Alternatively, in a similar manner as shown in FIG. 7 described previously, part of the glass substrate 2 may be removed to form columnar portions 2c, with air or ITO, having a different refractive index from the glass substrate 2, filling around the columnar portions 2c.

The dispersive layer 7 may be formed between the transparent electrode 4 and the light emitting layer 5. This too helps obtain higher light extraction efficiency. In this case, the first medium 31 is a transparent, electrically conductive material such as ITO, and the second medium 32 is air or the material of which the light emitting layer 5 is formed. Alternatively, in a similar manner as shown in FIG. 7 described previously, columnar portions 2c of the second medium 32 may be formed of a transparent, electrically conductive material.

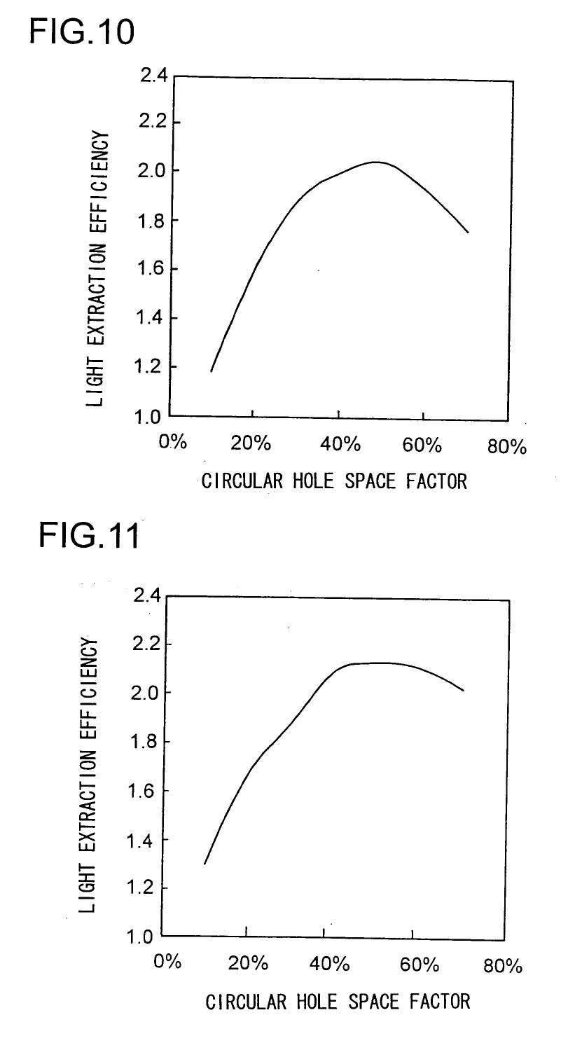

FIG. 10 is a diagram showing the results of a simulation of the light extraction efficiency of the planar light emitting device 1 that uses the two-dimensional diffraction grating 30 having the tetragonal lattice shown in FIG. 2 described previously. The first medium 31 is glass, and the second medium 32 is air. The vertical axis represents the light extraction efficiency for light having a wavelength of 520 nm as observed when the light emitting layer 5 is formed of a green light emitting material having a peak at a wavelength of 520 nm, assuming that the light extraction efficiency equals 1 when the diffractive layer 3 is omitted.

The horizontal axis represents the circular hole space factor, that is, the rate of the area occupied by the cylindrical holes 2b to the total area of the two-dimensional diffraction grating 30 (here, the space factor equals the rate of the area occupied by the second medium 32 to the sum of the areas occupied by the first and second media 31 and 32; moreover, since the diffractive layer 3 has an even thickness, the space factor also equals the rate of the volume occupied by the second medium 32 to the sum of the volumes occupied by the first and second media 31 and 32). The tetragonal lattice has a pitch T of 300 nm, and the holes 2b have a depth of 200 nm. The diameter of the holes 2b is varied.

FIG. 10 shows that higher light extraction efficiency is obtained over the whole range of the space factor of the second medium 32, with the peak light extraction efficiency obtained when the space factor is 50% and very high light extraction efficiency around the peak.

Samples of the planar light emitting device 1 were actually fabricated so that the holes 2b had a diameter of 150 nm in one sample and 220 nm in another and a depth of 200 nm, and that the lattice was tetragonal with a pitch T of 300 nm. The fabrication procedure involved forming the holes 2b in the glass substrate 2 by photolithograph and dry etching, then laying a film of ITO under conditions that permitted the holes 2b to be filled with air, and then laying an organic light emitting layer and a layer of aluminum in this order.

When the holes 2b had a diameter of 150 nm, the space factor was 19.6% (when converted to the ratio of the area of the second medium 32 to the area of the first medium 31, corresponding to 24.4%). When the holes 2b had a diameter of 220 nm, the space factor was 42.2% (when converted to the ratio of the area of the second medium 32 to the area of the first medium 31, corresponding to 73.0%).

The results were as follows: the light extraction efficiency of the planar light emitting device 1 was, in comparison with its value obtained when the diffractive layer 3 was omitted, 1.2 times that value when the holes 2b had a diameter of 150 nm and 1.8 times that value when the diameter was 220 nm. These results show a tendency similar to that the results obtained in the simulation shows.

FIG. 11 is a diagram showing the results of a typical simulation of the light extraction efficiency of another example of the planar light emitting device 1 that uses the two-dimensional diffraction grating 30 having the tetragonal lattice shown in FIG. 2 described previously. Here, the first medium 31 is glass, and the second medium 32, is ITO. In other respects, the structure here is the same as that of the planar light emitting device 1 shown in FIG. 10.

FIG. 11 shows that higher light extraction efficiency is obtained over the whole range of the space factor of the second medium 32, with the peak light extraction efficiency obtained when the space factor is 50% and very high light extraction efficiency around the peak.

Samples of the planar light emitting device 1 were actually fabricated so that the holes 2b had a diameter of 150 nm (so that the space factor is 19.6%) in one sample and 220 nm (so that the space factor is 42.2%) in another and a depth of 200 nm, and that the lattice was tetragonal with a pitch T of 300 nm. The fabrication procedure involved forming the holes 2b in the glass substrate 2 by photolithograph and dry etching, then laying a film of ITO under conditions that permitted the holes 2b to be filled with ITO, and then laying an organic light emitting layer and a layer of aluminum in this order.

The results were as follows: the light extraction efficiency of the planar light emitting device 1 was, in comparison with its value obtained when the diffractive layer 3 was omitted, 1.2 times that value when the holes 2b had a diameter of 150 nm and 1.9 times that value when the diameter was 220 nm. These results show a tendency similar to that the results obtained in the simulation shows.

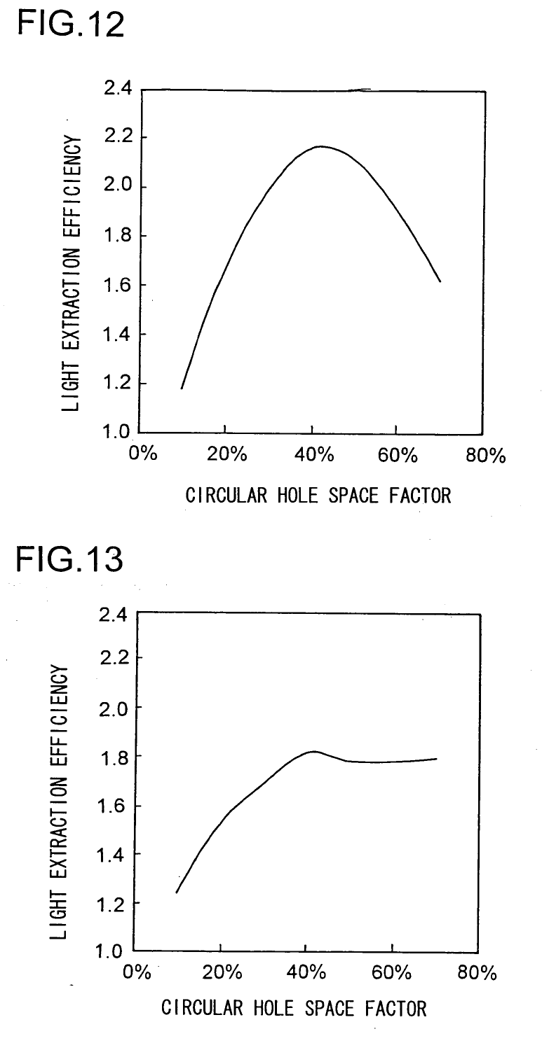

FIG. 12 is a diagram showing the results of a typical simulation of the light extraction efficiency of the planar light emitting device 1 that uses the two-dimensional diffraction grating 30 having the tetragonal lattice shown in FIG. 7 described previously. The vertical axis represents the light extraction efficiency for light having a wavelength of 520 nm as observed when the light emitting layer 5 is formed of a green light emitting material having a peak at a wavelength of 520 nm, assuming that the light extraction efficiency equals 1 when the diffractive layer 3 is omitted. The horizontal axis represents the circular hole space factor, that is, the rate of the area occupied by the cylindrical columnar portions 2c to the total area of the two-dimensional diffraction grating 30. The first medium 31 is are, and the second medium 32 is glass. The tetragonal lattice has a pitch T of 300 nm, and the columnar portions 2c have a height of 200 nm. The diameter of the columnar portions 2c is varied.

FIG. 12 shows that higher light extraction efficiency is obtained over the whole range of the space factor of the second medium 32, with the peak light extraction efficiency obtained when the space factor is 43% and very high light extraction efficiency around the peak.

FIG. 13 is a diagram showing the results of a typical simulation of the light extraction efficiency of another example of the planar light emitting device 1 that uses the two-dimensional diffraction grating 30 having the tetragonal lattice shown in FIG. 7 described previously. Here, the first medium 31 is ITO, and the second medium 32, is glass. In other respects, the structure here is the same as that of the planar light emitting device 1 shown in FIG. 12.

FIG. 13 shows that higher light extraction efficiency is obtained over the whole range of the space factor of the second medium 32, with the peak light extraction efficiency obtained when the space factor is 42% and very high light extraction efficiency around the peak.

FIGS. 10 to 13 show the following. When the ratio of the area occupied by the second medium to the sum of the areas occupied by the first and second media is set in the range from 25% to 60%, regardless of how the first and second media are combined, how the second medium is arrayed, and the like, it is possible to obtain very high light extraction efficiency corresponding to about 85% or more of the peak light extraction efficiency. When the above ratio is set in the range from 30% to 55%, it is possible to obtain still higher light extraction efficiency, specifically very high light extraction efficiency corresponding to about 90% or more of the peak light extraction efficiency.

Next, a third embodiment of the invention will be described. The two-dimensional diffraction grating 30 shown in FIG. 2 described previously has a tetragonal lattice in which portions of the second medium 32 having a circular cross-sectional shape are arrayed two-dimensionally in the first medium 3 1. On the other hand, the two-dimensional diffraction grating 30 shown in FIG. 6D described previously has a hexagonal lattice in which portions of the second medium 32 having a circular cross-sectional shape are arrayed two-dimensionally in the first medium 31

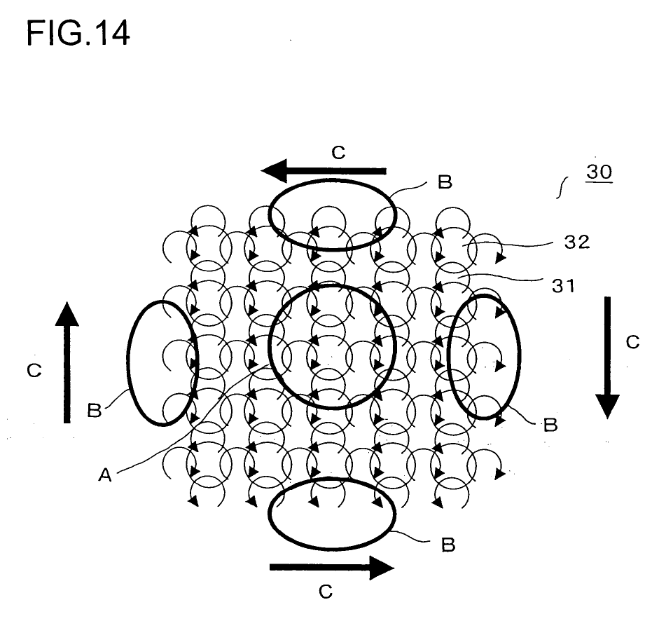

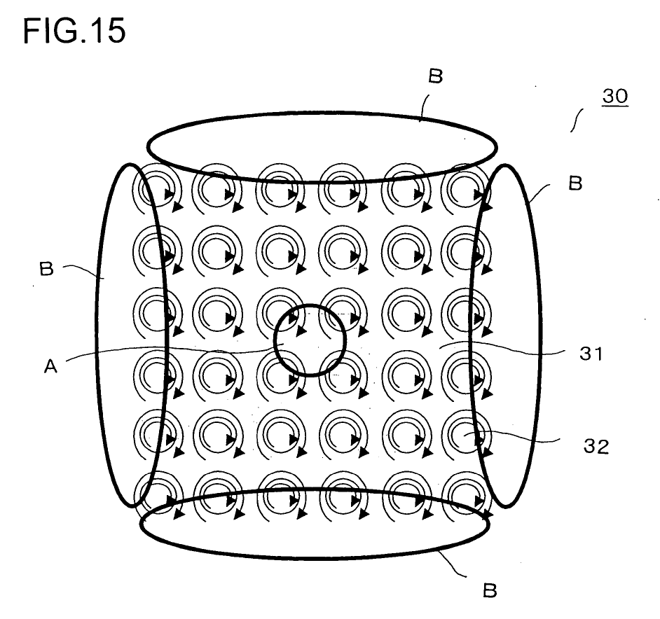

With respect to these two-dimensional diffraction gratings 30, varying types of light exhibit varying patterns of distribution. Light of which the wavelength is equal to the pitch of the tetragonal lattice shown in FIG. 2 exhibits high diffraction efficiency. An example of such light is light having such a wavelength as to exhibit a distribution as shown in FIGS. 14 and 15 when only the electric field components of light distributed over the two-dimensional refractive index period distribution are extracted and illustrated. In FIGS. 14 and 15, arc-shaped arrows indicate the electric field components.

In FIGS. 14 and 15, in a central portion A of the two-dimensional diffraction grating 30, even when light is bent in the vertical direction by diffraction, electric fields cancel each other, and thus the intensity of light is diminished. By contrast, in peripheral portions B of the two-dimensional diffraction grating 30, electric fields do not cancel each other, and thus light can be extracted as indicated by arrows C.

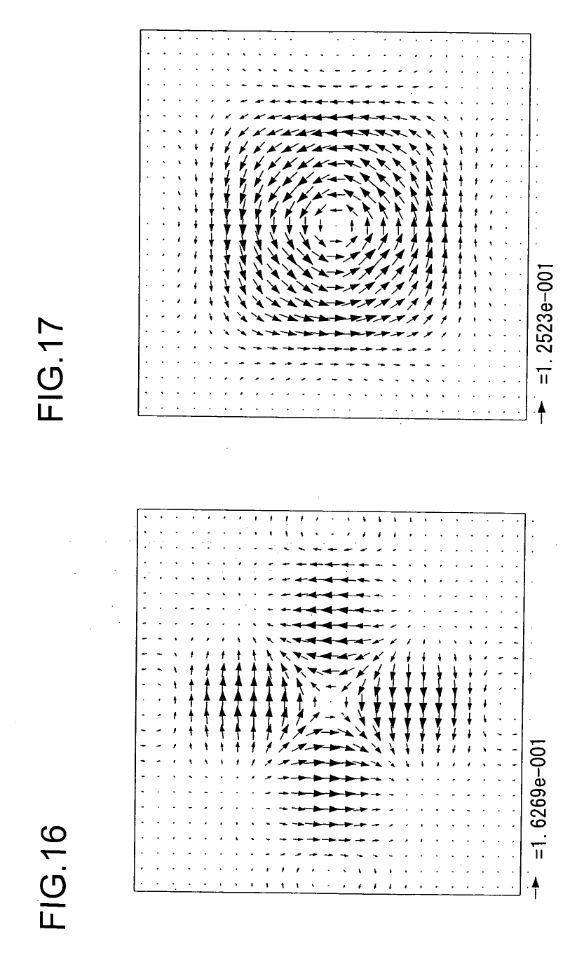

Thus, the electric field distribution of the light extracted by diffraction is, for example, as shown in FIGS. 16 and 17. In these diagrams, vectors indicate the direction and intensity of electric fields. FIGS. 16 and 17 correspond to the cases shown in FIGS. 14 and 15, respectively. In this way, while a large amount of light can be extracted in the peripheral portions B of the two-dimensional diffraction grating 30, that is impossible in the central portion A thereof, making it impossible to obtain satisfactorily higher light extraction efficiency.

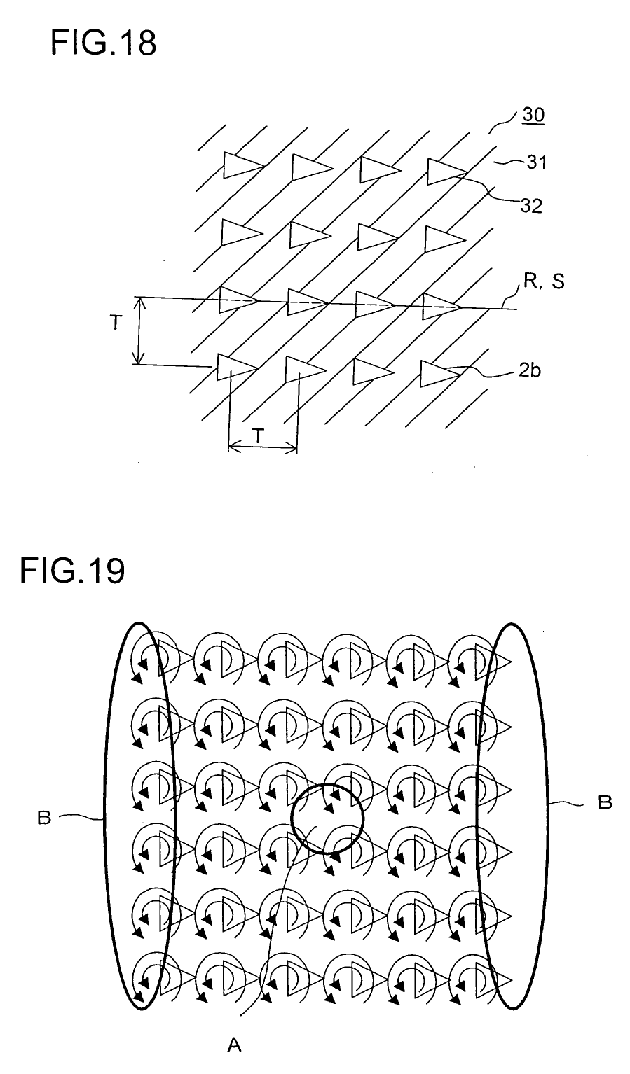

FIGS. 18 and 19 are a plan view and a side sectional view, respectively, of the two-dimensional diffraction grating 30 forming a diffractive layer 3 in the planar light emitting device 1 of this embodiment. The two-dimensional diffraction grating 30 is formed by forming holes 2b having an isosceles-triangular cross-sectional shape with a predetermined pitch T in a substrate 2, for example by forming a mask pattern by photolithograph and then performing dry etching.

In this way, in a first medium 31, namely the glass substrate 2 having a refractive index of 1.5, a second medium 32, namely hollow holes having a refractive index of 1, is arrayed to form a tetragonal lattice having a two-dimensional periodic structure. Moreover, the two-dimensional diffraction grating 30 is composed of a wallpaper group having a structure represented by an IUC classification symbol (hereinafter an “IUC symbol”) pm defined by International Union of Crystallography (IUCr) in 1952, and is non-rotation-symmetric. Moreover, the two-dimensional periodic structure has a pitch T of 0.1 μm to 4 μm.

In the planar light emitting device 1, structured as described above, when a voltage is applied or a current is injected between the transparent electrode 4 and the back electrode 6, the light emitting layer 5 emits light. The emitted light passes through the transparent electrode 4, and is then diffracted by the diffractive layer 3 in the direction of the exit surface 2a (see FIG. 1). The light then passes through the glass substrate 2, and exits via the exit surface 2a. Part of the light is reflected on the transparent electrode 4 to reach the transparent electrode 4, and is then diffracted likewise by the diffractive layer 3 to exit via the exit surface 2a.

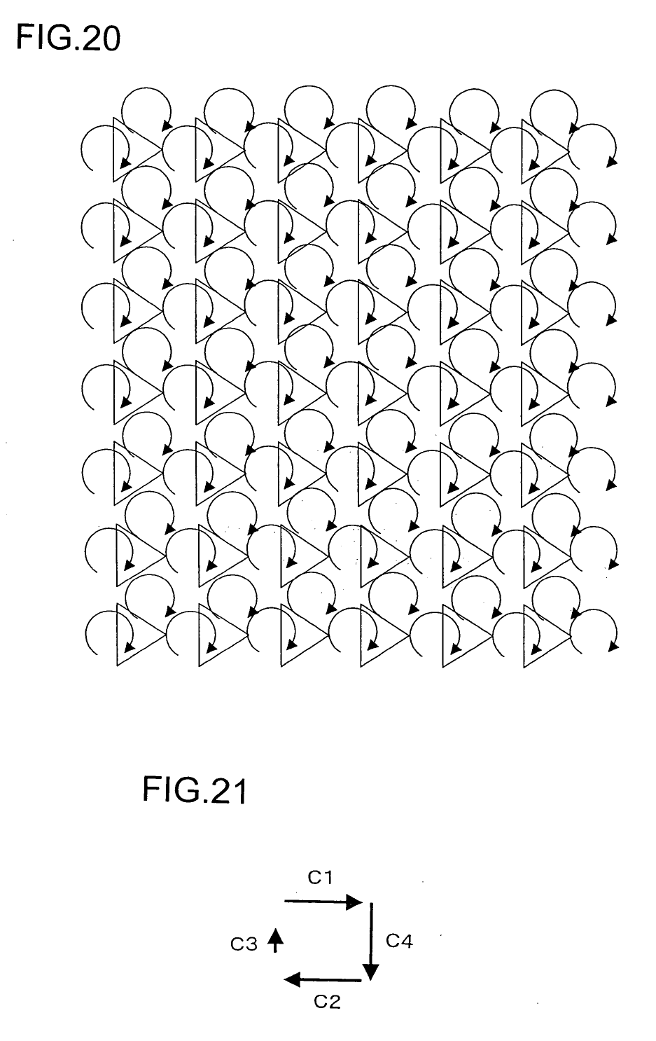

In a case where the pitch T equals the wavelength of the light, when, for example, only the electric field components of light distributed over the two-dimensional refractive index period distribution are extracted and illustrated, their distribution is as shown in FIGS. 19 and 20. In FIGS. 19 and 20, arc-shaped arrows indicate electric field components.

In FIG. 19, in peripheral portions B of the two-dimensional diffraction grating 30, electric fields do not cancel each other, and thus light can be extracted. In a central portion A of the two-dimensional diffraction grating 30, as shown in FIG. 21, in the widthwise directions, electric field indicated by vectors C1 and C2 cancel each other, and thus the intensity of light is diminished; in the lengthwise directions, however, because of the non-symmetric structure, one of vectors C3 and C4 surpasses the other, and thus light can be extracted. The same applies to the case shown in FIG. 20.

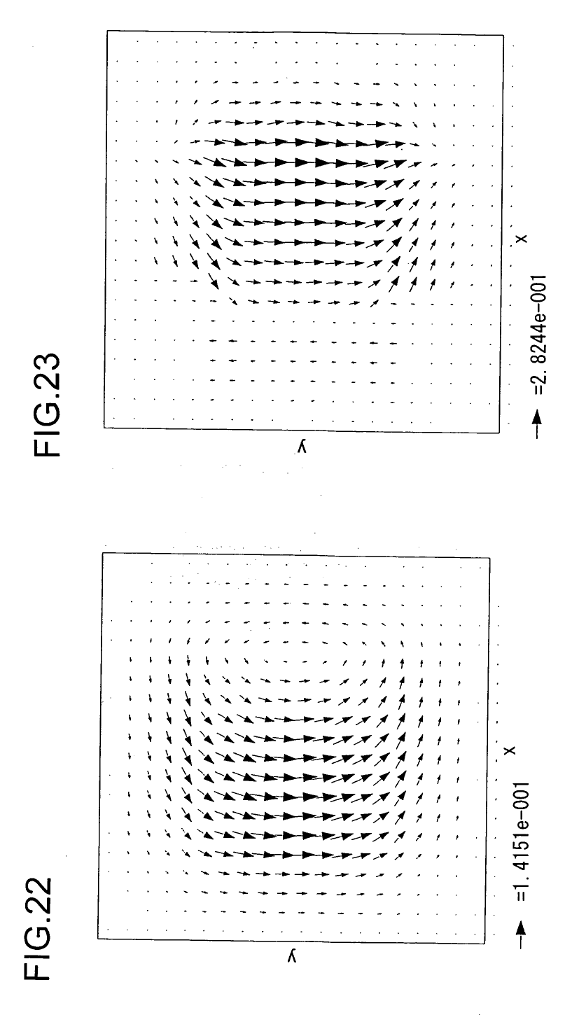

Thus, the electric field distribution of the light extracted by diffraction is, for example, as shown in FIGS. 22 and 23. In these diagrams, vectors indicate the direction and intensity of electric fields. FIGS. 22 and 23 correspond to the cases shown in FIGS. 19 and 20, respectively. In this way, it is possible to obtain higher light extraction efficiency than with the two-dimensional diffraction gratings shown in FIGS. 2 and 6D described previously (these are composed of a wallpaper group represented by symbols p4m and p6m, respectively).

For the two-dimensional diffraction grating 30 to function as a diffraction grating, its refractive index needs to be so distributed as to exhibit a certain kind of periodicity (so-called translation-symmetry). In this embodiment, the two-dimensional diffraction grating 30 is composed of a wallpaper group represented by an IUC symbol pm, and this reduces the cancellation of light in a central portion of the structure in the electric field distribution of the light extracted in the vertical direction by diffraction.

Likewise, when the two-dimensional diffraction grating 30 is so structured as to be translation-symmetric but non-rotation-symmetric, it is possible to reduce cancellation of light in a central portion of the structure. Specifically, by composing the two-dimensional diffraction grating 30 of a wallpaper group having a type of symmetry represented by one of symbols pl, pm, pg, and cm, it is possible to reduce cancellation of light.

In this embodiment, the two-dimensional diffraction grating 30 is non-rotation-symmetric, and this makes it possible to extract light with higher efficiency. Moreover, the two-dimensional diffraction grating 30 has a pitch T of 0.1 μm to 4 μm, and this makes it easy to design the two-dimensional diffraction grating 30 to diffract light in a desired direction.

The diffractive layer 3, when formed between the transparent electrode 4 and the glass substrate 2, is comparatively easy to produce and, since there it is located close to the light emitting layer 5, tends to work effectively. Alternatively, the diffractive layer 3 may be formed on the exit surface 2a. The second medium 32 has simply to have a different refractive index from the first medium 31. Thus, the holes 2b (see FIG. 18) may be filled with a transparent, electrically conductive material such as ITO. In this case, the two-dimensional diffraction grating 30 has, as the first medium 31, glass having a refractive index of 1.5 and, as the second medium 32, for example, ITO having a refractive index of 1.9.

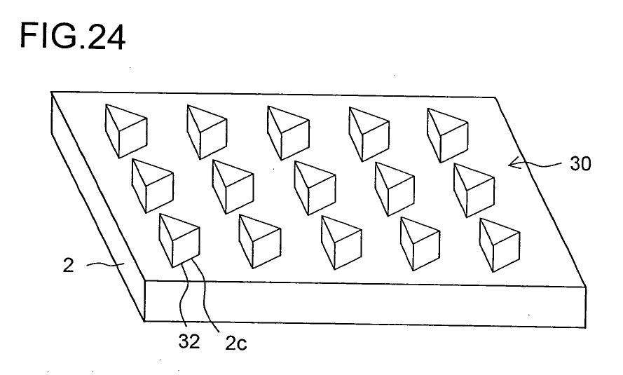

Alternatively, as shown in FIG. 24, the two-dimensional diffraction grating 30 may be formed by removing part of the glass substrate 2 so as to leave columnar portions 2c and then filling a material, such as air or ITO, having a different refractive index from the glass substrate 2, around the columnar portions 2c. In this case, the medium that fills around the columnar portions 2c is the first medium 31, and the columnar portions 2c is the second medium 32.

The diffractive layer 3 may be formed between the transparent electrode 4 and the light emitting layer 5. This too helps obtain higher light extraction efficiency. In this case, the first medium 31 is a transparent, electrically conductive material, such as ITO, and the second medium 32 is air or the material of which the light emitting layer 5 is formed.

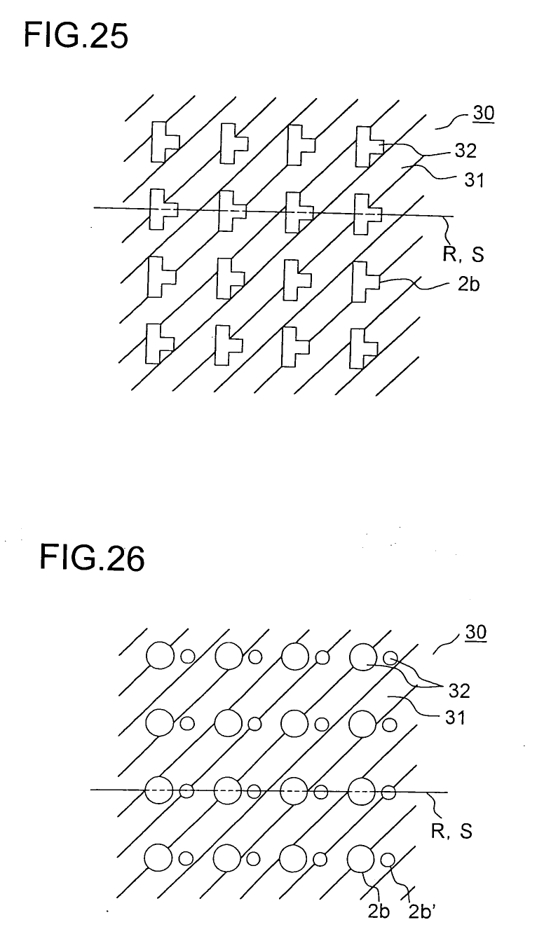

FIG. 25 is a plan view of the two-dimensional diffraction grating 30 used in the planar light emitting device 1 of a fourth embodiment of the invention. In this embodiment, the two-dimensional diffraction grating 30 has a tetragonal lattice, and the second medium 32 is arrayed as hollow holes of which the cross-section is T-shaped so as to be symmetric about an axis aligned with the direction of periodicity. Thus, the two-dimensional diffraction grating 30 is composed of a wallpaper group represented by an IUC symbol pm, is non-rotation-symmetric, and has a reflection symmetry axis R and a glide reflection symmetry axis S that are coincident with each other. In this embodiment, as in the third embodiment, it is possible to reduce cancellation of light in a central portion of the structure and thereby to obtain higher light extraction efficiency.

FIG. 26 is a plan view of the two-dimensional diffraction grating 30 used in the planar light emitting device 1 of a fifth embodiment of the invention. In this embodiment, the two-dimensional diffraction grating 30 has a tetragonal lattice, and the second medium 32 is arrayed as hollow large and small holes 2b and 2b′ having a circular cross-sectional shape and arranged side by side in the direction of periodicity. Thus, the two-dimensional diffraction grating 30 is composed of a wallpaper group represented by an IUC symbol pm, is non-rotation-symmetric, and has a reflection symmetry axis R and a glide reflection symmetry axis S that are coincident with each other. In this embodiment, as in the third embodiment, it is possible to reduce cancellation of light in a central portion of the structure and thereby to obtain higher light extraction efficiency.

FIG. 27 is a plan view of the two-dimensional diffraction grating 30 used in the planar light emitting device 1 of a sixth embodiment of the invention. In this embodiment, the two-dimensional diffraction grating 30 has a tetragonal lattice of which the unit lattice U is square, and has hollow holes 2b having a circular cross-sectional shape arrayed therein. Moreover, smaller hollow holes 2b′ are arrayed, one by the side of every second one of the holes 2b in the direction of periodicity, so that the holes 2b and 2b′ together form the second medium 32. Thus, the two-dimensional diffraction grating 30 is composed of a wallpaper group represented by an IUC symbol pm, is non-rotation-symmetric, and has a reflection symmetry axis R and a glide reflection symmetry axis S that are coincident with each other. In this embodiment, as in the third embodiment, it is possible to reduce cancellation of light in a central portion of the structure and thereby to obtain higher light extraction efficiency.

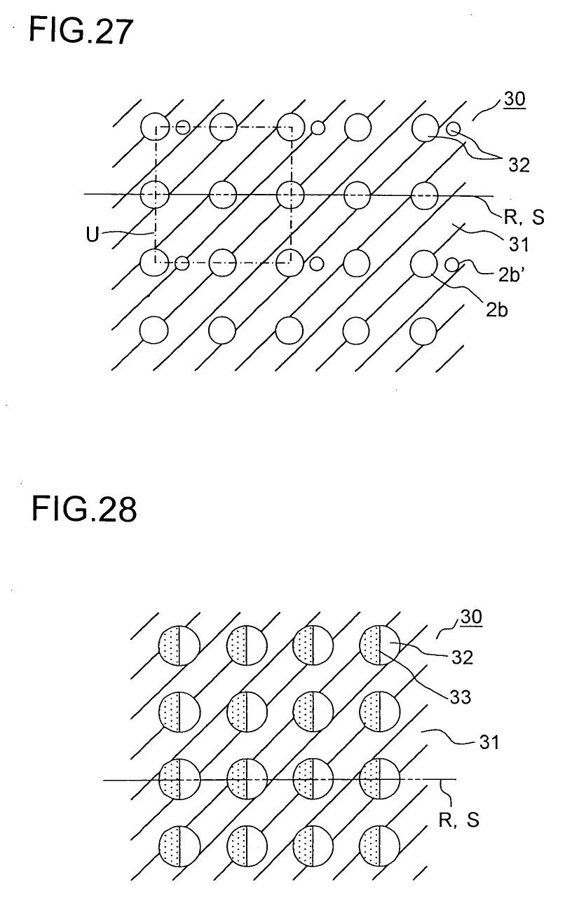

FIG. 28 is a plan view of the two-dimensional diffraction grating 30 used in the planar light emitting device 1 of a seventh embodiment of the invention. In this embodiment, the two-dimensional diffraction grating 30 has a tetragonal lattice, and the second medium 32 is arrayed as hollow holes having a semicircular cross-sectional shape. Moreover, contiguous with the second medium 32, a third medium 33 having a different refractive index from the first and second media 31 and 32 is arrayed to have a semicircular cross-sectional shape.

Thus, the two-dimensional diffraction grating 30 is composed of a wallpaper group represented by an IUC symbol pm, is non-rotation-symmetric, and has a reflection symmetry axis R and a glide reflection symmetry axis S that are coincident with each other. In this embodiment, as in the third embodiment, it is possible to reduce cancellation of light in a central portion of the structure and thereby to obtain higher light extraction efficiency.

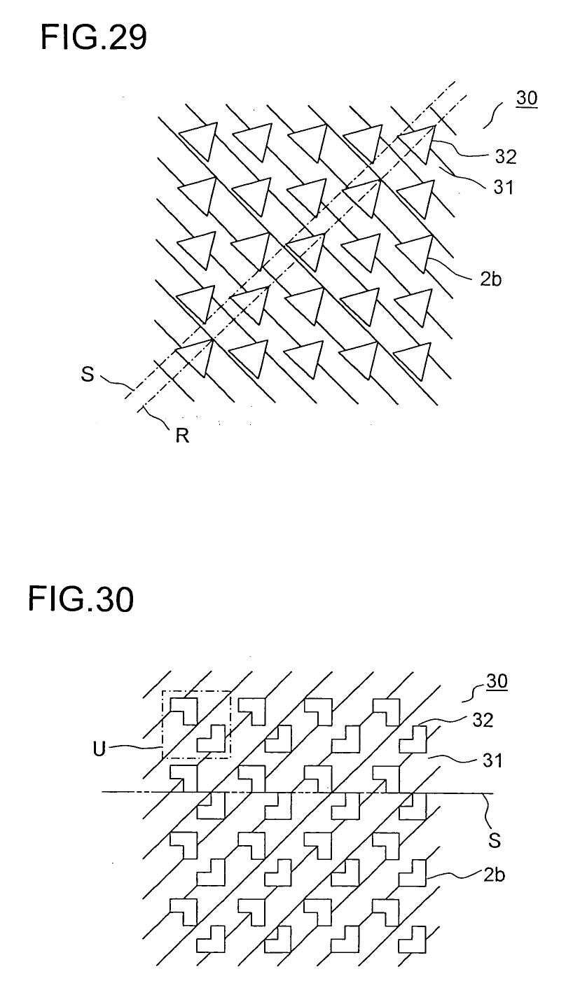

FIG. 29 is a plan view of the two-dimensional diffraction grating 30 used in the planar light emitting device 1 of an eighth embodiment of the invention. In this embodiment, the two-dimensional diffraction grating 30 has a tetragonal lattice, and the second medium 32 is arrayed as hollow holes having an isosceles-triangular cross-sectional shape symmetric about an axis inclined relative to the direction of periodicity. Thus, the two-dimensional diffraction grating 30 is composed of a wallpaper group represented by an IUC symbol cm, is non-rotation-symmetric, and has a reflection symmetry axis R and a glide reflection symmetry axis S that are separate from each other.

In a central portion of the structure, in the direction parallel to the reflection symmetry axis R, electric fields cancel each other, and thus the intensity of light is diminished. In the direction perpendicular to the reflection symmetry axis R, however, since the structure is non-symmetric, electric fields acting in one direction surpass those acting in the other direction, and thus light can be extracted. Thus, as in the third embodiment, it is possible to reduce cancellation of light in a central portion of the structure and thereby to obtain higher light extraction efficiency.

FIG. 30 is a plan view of the two-dimensional diffraction grating 30 used in the planar light emitting device 1 of a ninth embodiment of the invention. In this embodiment, the two-dimensional diffraction grating 30 has a tetragonal lattice of which the unit lattice U is square, and the second medium 32 is arrayed as hollow holes having an L-shaped cross-sectional shape, with the hollow holes arranged in two different orientations so that every two of them are 90° rotated relative to each other. Thus, the two-dimensional diffraction grating 30 is composed of a wallpaper group represented by an IUC symbol pg, is non-rotation-symmetric, and has no reflection symmetry axis but a glide reflection symmetry axis S.

In a central portion of the structure, in the direction parallel to the glide reflection symmetry axis S, electric fields cancel each other, and thus the intensity of light is diminished. In the direction perpendicular to the glide reflection symmetry axis S, however, since the structure is non-symmetric, at every lattice point, electric fields acting in one direction with respect to the glide reflection symmetry axis surpass those acting in the other direction, and thus light can be extracted. Thus, as in the third embodiment, it is possible to reduce cancellation of light in a central portion of the structure and thereby to obtain higher light extraction efficiency.

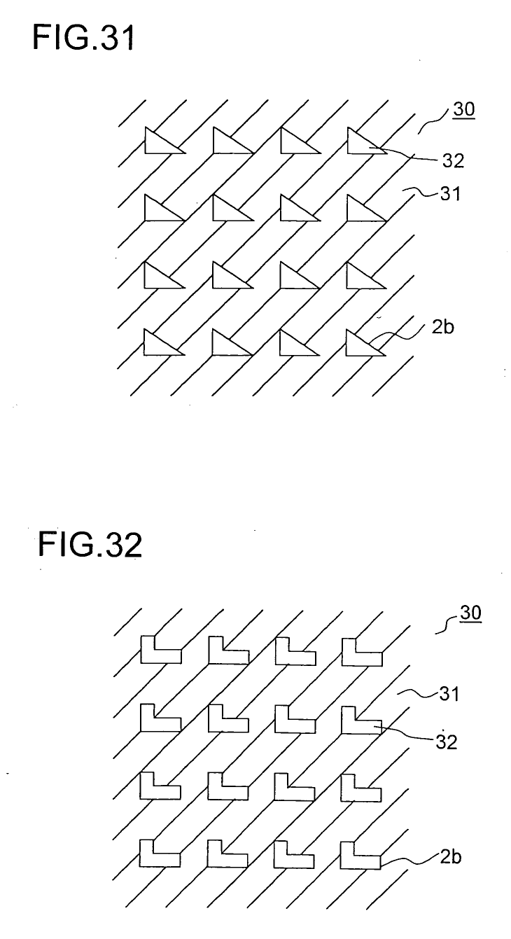

FIG. 31 is a plan view of the two-dimensional diffraction grating 30 used in the planar light emitting device 1 of a tenth embodiment of the invention. In this embodiment, the two-dimensional diffraction grating 30 has a tetragonal lattice, and the second medium 32 is arrayed as hollow holes having a right-angled-triangular cross-sectional shape. Thus, the two-dimensional diffraction grating 30 is composed of a wallpaper group represented by an IUC symbol pl, is non-rotation-symmetric, and has no reflection symmetry axis and no glide reflection symmetry axis.

In this embodiment, in a central portion of the structure, not only in the lengthwise directions, but also in the widthwise directions, cancellation between electric fields can be further reduced than in the third to ninth embodiment. Thus, it is possible to further reduce cancellation of light in a central portion of the structure and thereby to obtain still higher light extraction efficiency.

FIG. 32 is a plan view of the two-dimensional diffraction grating 30 used in the planar light emitting device 1 of an eleventh embodiment of the invention. In this embodiment, the two-dimensional diffraction grating 30 has a tetragonal lattice, and the second medium 32 is arrayed as hollow holes having a L-shaped cross-sectional shape. Thus, the two-dimensional diffraction grating 30 is composed of a wallpaper group represented by an IUC symbol pl, is non-rotation-symmetric, and has no reflection symmetry axis and no glide reflection symmetry axis. In this embodiment, as in the tenth embodiment, it is possible to reduce cancellation of light in a central portion of the structure and thereby to obtain higher light extraction efficiency.

The present invention finds application in planar light emitting devices such as organic and inorganic LE devices.

What is claimed is:

1. A planar light emitting device comprising:
a light emitting layer that is formed on a substrate and that emits light when a voltage is applied thereto or a current is injected thereinto; and
a two-dimensional diffraction grating that has a first and a second medium having different refractive indices and that has the second medium arrayed two-dimensionally in the first medium,
wherein, in the two-dimensional diffraction grating, a ratio of an area occupied by the second medium to a sum of an area occupied by the first medium and the area occupied by the second medium is 25% or more but 60% or less.

2. The planar light emitting device of claim 1,
wherein the two-dimensional diffraction grating has a grating pitch of 0.1 μm to 4 μm.

3. The planar light emitting device of claim 1,
wherein the first medium is the substrate, and the second medium fills holes formed in the substrate.

4. The planar light emitting device of claim 1,
wherein the second medium is the substrate, and the first medium fills around columnar portions formed by removing part of the substrate.

5. The planar light emitting device of claim 1,
wherein, of the first and second media, one is glass and the other is air or a transparent electrode.

6. The planar light emitting device of claim 1,
wherein, of the first and second media, one is a transparent electrode and the other is air or a material of which the light emitting layer is formed.

7. A planar light emitting device comprising:
a light emitting layer that is formed on a substrate and that emits light when a voltage is applied thereto or a current is injected thereinto; and
a diffractive layer formed with a two-dimensional diffraction grating that has a first and a second medium having different refractive indices and that has the second medium arrayed two-dimensionally in the first medium,
wherein, in the diffractive layer, a ratio of an area occupied by the second medium to a sum of an area occupied by the first medium and the area occupied by the second medium is 25% or more but 60% or less.

8. A planar light emitting device comprising:
a light emitting layer that is formed on a substrate and that emits light when a voltage is applied thereto or a current is injected thereinto; and
a dispersive member that has a first and a second medium having different refractive indices and that has the second medium arrayed two-dimensionally in the first medium,
wherein, in the dispersive member, a ratio of an area occupied by the second medium to a sum of an area occupied by the first medium and the area occupied by the second medium is 25% or more but 60% or less.

9. The planar light emitting device of claim 8,
wherein two adjacent portions of the second medium are apart from each other at a mean interval of 0.1 μm to 4 μm.

10. The planar light emitting device of claim 8,
wherein the first medium is the substrate, and the second medium fills holes formed in the substrate.

11. The planar light emitting device of claim 8,
wherein the second medium is the substrate, and the first medium fills around columnar portions formed by removing part of the substrate.

12. The planar light emitting device of claim 8,
wherein, of the first and second media, one is glass and the other is air or a transparent electrode.

13. The planar light emitting device of claim 8,
wherein, of the first and second media, one is a transparent electrode and the other is air or a material of which the light emitting layer is formed.

14. A planar light emitting device comprising:
a light emitting layer that is formed on a substrate and that emits light when a voltage is applied thereto or a current is injected thereinto; and
a dispersive layer formed with a dispersive member that has a first and a second medium having different refractive indices and that has the second medium arrayed two-dimensionally in the first medium,
wherein, in the dispersive layer, a ratio of an area occupied by the second medium to a sum of an area occupied by the first medium and the area occupied by the second medium is 25% or more but 60% or less.

15. A planar light emitting device comprising:
a light emitting layer that is formed on a substrate and that emits light when a voltage is applied thereto or a current is injected thereinto; and
a two-dimensional diffraction grating that has a first and a second medium having different refractive indices arrayed two-dimensionally,
wherein the two-dimensional diffraction grating is non-rotation-symmetric.

16. The planar light emitting device of claim 15,
wherein the two-dimensional diffraction grating has a grating pitch of 0.1 μm to 4 μm.

17. The planar light emitting device of claim 15,
wherein the two-dimensional diffraction grating has a tetragonal lattice in which the first medium is the substrate, and the second medium fills holes formed in the substrate to have a triangular cross-sectional shape.

18. The planar light emitting device of claim 15,
wherein, of the first and second media, one is glass and the other is air or a transparent electrode.

19. The planar light emitting device of claim 15,
wherein, of the first and second media, one is a transparent electrode and the other is air or a material of which the light emitting layer is formed.

20. A planar light emitting device comprising:
a light emitting layer that is formed on a substrate and that emits light when a voltage is applied thereto or a current is injected thereinto; and
a two-dimensional diffraction grating that has a first and a second medium having different refractive indices arrayed two-dimensionally,
wherein the two-dimensional diffraction grating has a periodic structure which is classified into pl, pm, pg, or cm by a classification method under IUC (International Union of Crystallography in 1952).

21. The planar light emitting device of claim 20,
wherein the two-dimensional diffraction grating has a grating pitch of 0.1 μm to 4 μm.

22. The planar light emitting device of claim 20,
wherein the two-dimensional diffraction grating has a tetragonal lattice in which the first medium is the substrate, and the second medium fills holes formed in the substrate to have a triangular cross-sectional shape.

23. The planar light emitting device of claim 20,
wherein, of the first and second media, one is glass and the other is air or a transparent electrode.

24. The planar light emitting device of claim 20,
wherein, of the first and second media, one is a transparent electrode and the other is air or a material of which the light emitting layer is formed.
